(19) United States
(12) Patent Application Publication
(10) Pub. No.: US 2008/0112113 A1
(43) Pub. Date: May 15, 2008

(54) PORTABLE ELECTRONIC DEVICE INCLUDING HINGE ASSEMBLY WITH USER INTERFACE ELEMENT

(75) Inventors: MICHAEL J. SAWADSKI, MT. PROPSECT, IL (US); ROGER J. JELLICOE, WOODSTOCK, IL (US); GILES D. McWILLIAM, CHICAGO, IL (US); KARL R. VOSS, SCHAUMBURG, IL (US)

Correspondence Address: MOTOROLA INC, 600 NORTH US HIGHWAY 45, W4 - 39Q, LIBERTYVILLE, IL, 60048-5343, US

(73) Assignee: MOTOROLA, INC., LIBERTYVILLE, IL (US)

(21) Appl. No.: 11/559,643

(22) Filed: Nov. 14, 2006

(51) Int. Cl. H05K 5/00

(52) U.S. Cl. 361/680; 361/679; 361/681

(57) ABSTRACT

A portable electronic device, for example, a cellular telephone, (100) including a hinge assembly (106) interconnecting first and second housing portions, wherein the housing portions are pivotal about respective non-collinear pivot axes, and a user-interface element, for example, an image capture or a display device, disposed on the hinge assembly.

### FIELD OF THE DISCLOSURE

The present disclosure relates generally to portable electronic devices, and more particularly to portable electronic devices implemented in hinged housing assemblies, for example, clam-shell style cellular telephone handsets, wherein hinge assembly includes one or more user-interface elements and hinge assemblies therefor.

### BACKGROUND

Portable electronic devices are known generally. Examples of such devices include cellular phones, audio and video playback devices, laptop computers, gaming devices and personal digital assistants (PDAs). The trend lately has been to integrate increasing functionality onto a single device without adversely affecting its portability. It is not uncommon, for example, to integrate image capture capability and audio/video playback in a portable wireless communication device. Some portable electronic devices are implemented in claim-shell style housings, which are compact and are currently considered chic by many users.

The various aspects, features and advantages of the instant disclosure will become more fully apparent to those having ordinary skill in the art upon careful consideration of the following Detailed Description with the accompanying drawings described below. The drawings may have been simplified for clarity and are not necessarily drawn to scale.

### BRIEF DESCRIPTION OF THE DRAWINGS

FIG. 1 illustrates a portable electronic device.

FIG. 2 illustrates a first view of a portable electronic device with a hinge assembly.

FIG. 3 illustrates a second view of a portable electronic device with the hinge assembly.

FIG. 4 illustrates a view of a stand-alone hinge assembly.

### DETAILED DESCRIPTION

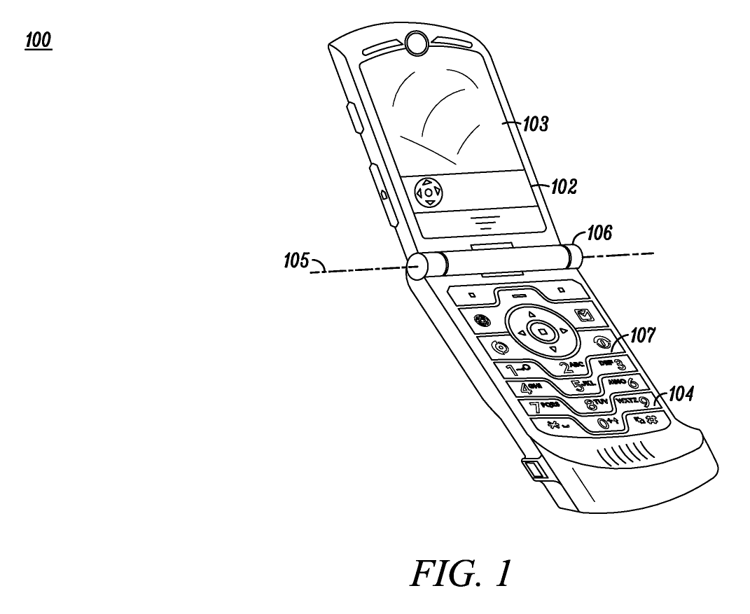

FIG. 1 illustrates a portable electronic device 100 comprising a first housing portion 102 and a second housing portion 104 interconnected by a hinge assembly 106. In one embodiment, the first housing portion is a flip and the second housing portion is a base. The portable electronic device may be selected from a group comprising a multimedia playback device, a mobile phone, a Personal Digital Assistant (PDA), and a gaming device. In other embodiments, the portable electronic device is implemented as some other form, for example, as a navigation unit, a receiver capable of receiving terrestrial or satellite signals, or a remote control device. Some implementations of the device may include combinations of these and other types of portable electronic devices. For example, a cellular telephone may include image capture, multimedia playback gaming, satellite navigation, and information management capabilities.

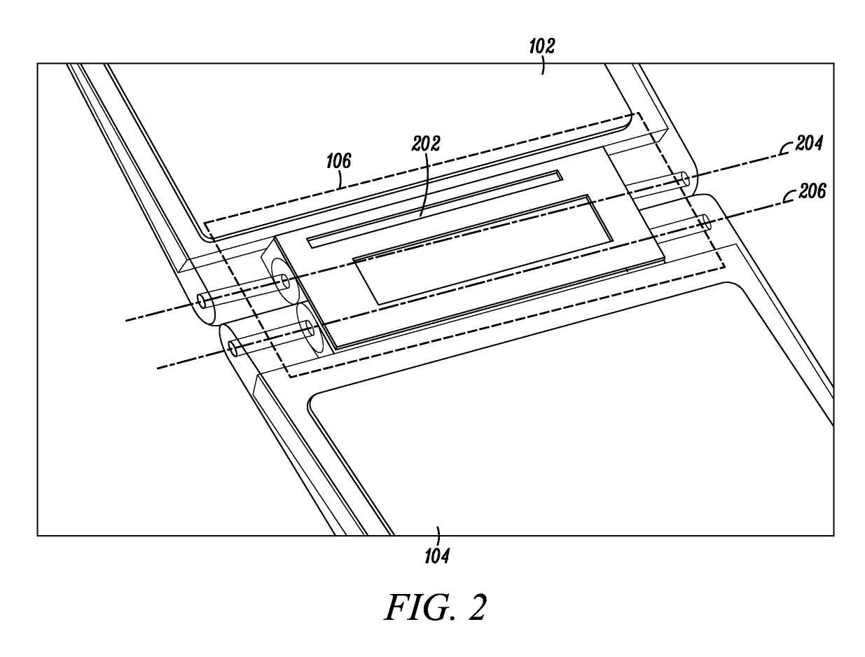

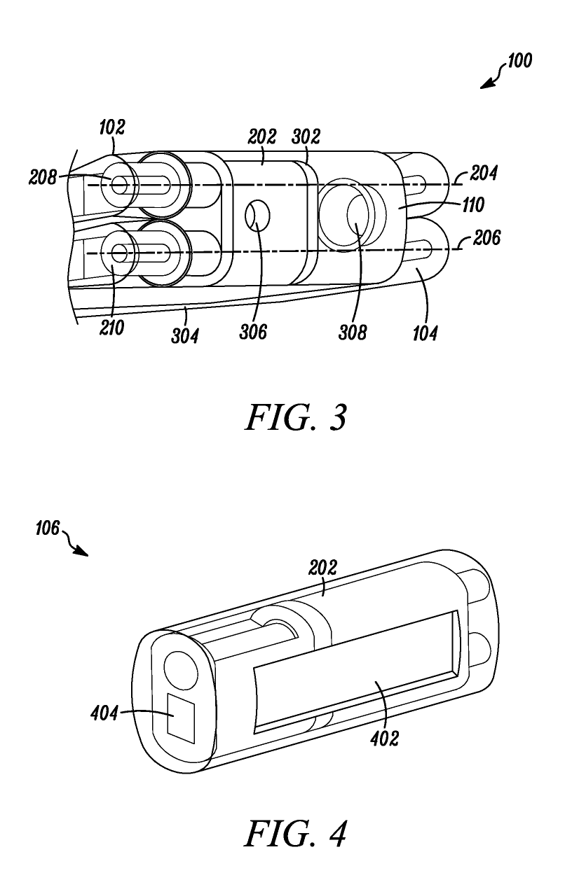

FIG. 2 illustrates a portion of a portable electronic device 100 including the hinge assembly 106. The assembly includes a body portion or housing 202 that includes one or more user-interface elements, as discussed more fully below. In FIG. 3, the hinge assembly comprises a first pivotal interconnect 208 disposed about a first pivot axis 204 and a second pivotal interconnect 210 disposed about a second axis 206, wherein the first and second pivot axes are non-collinear. In FIG. 2, an upper portion of the first housing portion 102 is pivotally connectable to the first pivotal interconnect of the hinge assembly and an upper portion of the second housing portion 104 is pivotally connectable to the second pivotal interconnect of the hinge assembly.

The details of the pivotal interconnect of the hinge assembly are not particularly relevant except for the fact that hinge assembly pivotally interconnects the first and second housing portions. The structural configuration of the pivotal interconnect need not be limited to any particular form. In FIG. 1, according to an alternative embodiment, the first and second housing portions 102 and 104 are pivotally coupled by a hinge assembly having a single pivot axis 105.

In one embodiment, the first housing portion is a flip and the second housing portion is a base. In FIG. 1, the first housing portion, or flip, 102 includes a first display device 103 on a first side thereof and in some embodiments, a second display on a second, opposite side of the flip and the second housing portion, or base, 104 includes a keypad 107 on at least one side thereof. In wireless communication applications, the first and second housing portions also typically include a radio transceiver, a controller or processor, one or more speakers, a microphone, possibly a touch screen and other user inputs and outputs known generally to those having ordinary skill in the art.

In some embodiments, the first and second housing portions have a relatively limited range of pivotal motion. In FIG. 1, for example, the flip 102 pivots open relative to the base 104 over an angular range that is less than 180 degrees. The hinge assembly typically includes structure limiting the range of pivoting motion or detents for positioning the housing portions at one or more particular angular orientations. In other embodiments, the hinge assembly may include structure for biasing the flip opened or closed and, in some implementations, structure for dampening the biased rotation of the flip. In the embodiment of FIG. 3, the first and second housing portions may pivot over a range of nearly 360 degrees.

In FIG. 3, the hinge assembly forms a top portion 110 having an outer surface of the portable electronic device 100 when the first and second housing portions are positioned on a closed configuration. In one embodiment, the user-interface element is an image capture module disposed in or on the hinge assembly. In some implementations, at least a portion of the image capture module is partially encapsulated within or captured by the hinge assembly. The image capture device may have still or video image capture capability. In embodiments that include video capture capability, the device may also include audio recording capability, wherein one or more microphones are located in the hinge assembly or in some other portion of the device, for example, in one or both housing portions.

In FIG. 3, the image capture module includes a lens 306 that focuses an image onto a sensor that disposed within the hinge assembly. In some embodiments, the lens may include structure for changing the focal length of the lens. The exemplary image capture assembly also includes a flash element 308. In FIG. 3, the lens is disposed on the outer surface of the top portion 110 of the portable electronic device when the device is in the closed configuration. In this embodiment, the optical axis of the lens is substantially perpendicular to the first and second pivot axes, 204 and 206. In some embodiments, the direction of the lens may be adjustable over some limited range such that the optical axis is not strictly perpendicular to the pivot axis.

In another embodiment, the user-interface element of the hinge assembly is a display and/or touch screen device. In FIG. 4, the display and/or touch screen device 402 is disposed on the outer surface of the top portion of the portable electronic device. In this embodiment, a planar surface of the display device is substantially perpendicular to opposite facing side portions of the first and second housing portions in the closed position. Thus in FIG. 3, if the outer surface of the top portion of the device included a display device, the planar surface of the display would be substantially perpendicular to the opposite side surfaces 302 and 304 of the housing portions.

In another embodiment, the user-interface element is a tactile device, for example, a vibrating transducer. FIG. 4 illustrates a vibrating device 404 disposed within hinge assembly. In other embodiments, the user-interface element is selected from a group comprising a camera, a keypad, a flash, a touch screen, a battery, a head jack, a power connection, a scrolling button, and audio transducers, inputs keys, among others. Some implementations may include multiple user-interface elements. In FIG. 4, for example, the hinge assembly includes a display device and a vibrator.

In some embodiments, the hinge assembly includes an electrical interface coupled to the user-interface element dispose on or within the hinge assembly, wherein the electrical interface is coupled to circuitry in either one or both of the first and second housing portions. In one embodiment, the electrical interface is embodied as or more conductors, for example, a conductor strip, extending from hinge assembly. In another embodiment, the electrical interface is a connector to which a conductor strip extending from one or both of the housing portions connects. In FIG. 3, for example, the image capture module is electrically coupled to a controller or memory or to other circuits housed within the flip or base via the interface. The vibrator 404 would include an interface to provide power. The particular configuration of the interface is dependent on the type of user-interface element or elements disposed within or on the hinge assembly. Some elements may require only power whereas other may require a data bus and or an address bus.

While the present disclosure and the best modes thereof have been described in a manner establishing possession by the inventors and enabling those of ordinary skill in the art to make and use the same, it will be understood and appreciated that there are many equivalents of the exemplary embodiments disclosed herein, and that modifications and variations may be made thereto, without departing from the scope and spirit of the invention, which is to be limited not by the exemplary embodiments but by the appended claims.

What is claimed is:

1. A portable electronic device comprising:
a first housing portion;
a second housing portion; and
a hinge assembly interconnecting the first and second housing portions, an upper portion of the first housing portion pivotally coupled to the hinge assembly about a first pivot axis and an upper portion of the second housing portion pivotally coupled to the hinge assembly about a second pivot axis,
the first and second pivot axes are non-collinear;
a user-interface element disposed on the hinge assembly.

2. The device of claim 1, the hinge assembly including an electrical interface, the electrical interface coupled to the user-interface element and to circuitry in the first housing portion.

3. The device of claim 1, the user-interface element is selected from a group comprising a camera, a keypad, a flash, a touch screen, a battery, a head jack, a power connection, a scrolling button, and a vibrator.

4. The device of claim 1, the user-interface element is an image capture module including a lens, the image capture module at least partially encapsulated by the hinge assembly.

5. The device of claim 4,
the hinge assembly forms an outer surface of a top portion of the portable electronic device when the first and second housing portions are pivoted to a closed position,
the lens is disposed on the outer surface of the top portion of the portable electronic device.

6. The device of claim 5, an optical axis of the lens substantially perpendicular to the first and second pivot axes.

7. The device of claim 6,
the first housing portion is a flip and the second housing portion is a base, the flip includes a first display device on a first side thereof and a second display on a second side thereof,
the second housing portion includes a keypad on at least one side thereof.

8. The device of claim 1,
the hinge assembly forms an outer surface of a top portion of the portable electronic device when the first and second housing portions are pivoted to a closed position,
the user-interface element is a display device disposed on the outer surface of the top portion of the portable electronic device.

9. The device of claim 8, a planar surface of the display substantially perpendicular to facing side portions of the first and second housing portions in the closed position.

10. The device of claim 1, wherein the portable electronic device is selected from a group comprising a multimedia playback device, a mobile phone, a Personal Digital Assistant (PDA), and a gaming device.

11. A hinge assembly for pivotally coupling first and second housing portions, the assembly comprising:
a body portion having a first pivotal interconnect with a first pivot axis and a second pivotal interconnect with a second pivot axis, the first and second pivot axes are non-collinear,
a first housing portion pivotally connectable to the first pivotal interconnect and a second housing portion pivotally connectable to the second pivotal interconnect,
a user-interface element coupled to the body portion.

12. The assembly of claim 11, an electrical interface disposed on the body portion, the electrical interface coupled to the user-interface element, the electrical interface connectable to housing portion circuitry.

13. The assembly of claim 11, the user-interface element is selected from the group comprising an image capture device, a keypad, a flash, a touch screen, a battery, a head-jack, a power connection, a scrolling button, a liquid crystal display, a headset jack, a discrete button, a security interface, and a vibrator.

14. The assembly of claim 11, the user-interface element comprises a user-interface function control button.

15. The assembly of claim 11, the user-interface element is an image capture module including a lens, the image capture module at least partially encapsulated by the hinge assembly.

16. The assembly of claim 11, the user-interface element is a display device disposed on the outer surface of the top portion of the portable electronic device.
